(19) United States
(12) Patent Application Publication
(10) Pub. No.: US 2025/0130597 A1
(43) Pub. Date: Apr. 24, 2025

(54) LIQUID SUPPLY DEVICE, LIQUID SUPPLY METHOD, AND STORAGE MEDIUM

(71) Applicant: Tokyo Electron Limited, Tokyo (JP)

(72) Inventors: So OSADA, Kikuchi-gun (JP); Katsuya OKUDA, Kumamoto (JP); Naohiro IWANAGA, Koshi City (JP); Kazuki KOSAI, Koshi City (JP); Toshiyuki SHIOKAWA, Koshi City (JP)

(21) Appl. No.: 18/917,105

(22) Filed: Oct. 16, 2024

(30) Foreign Application Priority Data
Oct. 23, 2023 (JP) 2023-181916
Aug. 2, 2024 (JP) 2024-126527

(51) Int. Cl. G05D 7/06; H01L 21/67

(52) U.S. Cl. CPC G05D 7/0617; H01L 21/67017

(57) ABSTRACT

A liquid supply device includes: a processing liquid line through which a processing liquid is supplied to a liquid processor for performing liquid processing on a substrate; a heating mechanism provided in the processing liquid line to heat the processing liquid flowing through the processing liquid line; a filter provided downstream of the heating mechanism in the processing liquid line; a drain line provided downstream of the filter in the processing liquid line and through which the processing liquid flowing through the processing liquid line is drained; a first temperature sensor configured to respectively detect a temperature of the filter, the processing liquid line, the drain line, or the processing liquid; and a controller configured to determine whether to drain the processing liquid from the drain line based on a detection result by the first temperature sensor.

### CROSS-REFERENCE TO RELATED APPLICATIONS

This application is based upon and claims the benefit of priority from Japanese Patent Application Nos. 2023-181916, filed on Oct. 23, 2023, and 2024-126527, filed on Aug. 2, 2024, respectively, the entire contents of each of which are incorporated herein by reference.

### TECHNICAL FIELD

The present disclosure relates to a liquid supply device, a liquid supply method, and a non-transitory computer-readable storage medium.

### BACKGROUND

In the related art, there is known a liquid processing apparatus which circulates a processing liquid for a substrate such as a semiconductor wafer (hereinafter also referred to as a wafer) through a circulation line and supplies the processing liquid to a processor via a branch line branched from the circulation line. The circulation line of the liquid processing apparatus is provided with a filter which removes foreign substances from the processing liquid.

### PRIOR ART DOCUMENT

### Patent Document

Patent Document 1: Japanese Laid-Open Patent Publication No. 2019-041039

### SUMMARY

According to one embodiment of the present disclosure, a liquid supply device includes: a processing liquid line through which a processing liquid is supplied to a liquid processor configured to perform liquid processing on a substrate; a heating mechanism provided in the processing liquid line and configured to heat the processing liquid flowing through the processing liquid line; a filter provided downstream of the heating mechanism in the processing liquid line; a drain line provided downstream of the filter in the processing liquid line and through which the processing liquid flowing through the processing liquid line is drained; a first temperature sensor provided in the filter, the processing liquid line located between the filter and the drain line, or the drain line, and configured to respectively detect a temperature of the filter, the processing liquid line, or the drain line, or to detect a temperature of the processing liquid; and a controller, wherein the controller is configured to determine whether or not to drain the processing liquid from the drain line based on a detection result obtained by the first temperature sensor.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram showing a schematic configuration of a substrate processing system according to a first embodiment.

FIG. 2 is a schematic diagram showing a configuration of a processing unit according to a first embodiment.

FIG. 3 is a diagram showing a schematic configuration of a processing liquid source according to an embodiment.

FIG. 4 is a diagram showing an example of state transitions of a pump, first to fourth valves, a first heating mechanism, and a second heating mechanism.

FIG. 5 is a schematic diagram showing an example of an operation of the processing liquid source according to the first embodiment.

FIG. 6 is a schematic diagram showing an example of an operation of the processing liquid source according to the first embodiment.

FIG. 7 is a schematic diagram showing an example of an operation of the processing liquid source according to the first embodiment.

FIG. 8 is a diagram showing a schematic configuration of a processing liquid source according to a second embodiment.

FIG. 9 is a diagram showing a schematic configuration of a processing liquid source according to a third embodiment.

FIG. 10 is a diagram showing an example of transitions in states of a pump, first to fourth valves, a seventh valve, an eighth valve, a first heating mechanism, and a second heating mechanism.

FIG. 11 is a schematic diagram showing an example of an operation of the processing liquid source according to the third embodiment.

FIG. 12 is a schematic diagram showing an example of the operation of the processing liquid source according to the third embodiment.

FIG. 13 is a schematic diagram showing an example of the operation of the processing liquid source according to the third embodiment.

FIG. 14 is a schematic diagram showing an example of the operation of the processing liquid source according to the third embodiment.

FIG. 15 is a diagram showing a schematic configuration of a processing liquid source according to a fifth embodiment.

FIG. 16 is a diagram showing a schematic configuration of a processing liquid source according to a sixth embodiment.

### DETAILED DESCRIPTION

Hereinafter, aspects (hereinafter referred to as “embodiments”) for embodying a liquid supply device, a liquid supply method, and a storage medium according to the present disclosure will be described with reference to the drawings. The present disclosure is not limited to these embodiments. Further, the respective embodiments may be appropriately combined with each other to the extent that processing contents are not contradictory. In addition, the same parts in the following embodiments will be designated by like reference numerals, and duplicated descriptions thereof will be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In addition, in the embodiments described below, expressions such as “constant”, “orthogonal”, “vertical” and “parallel” may be used. These expressions do not necessarily mean “strictly constant”, “strictly orthogonal”, “strictly vertical” and “strictly parallel”. In other words, each of the above expressions allows for, e.g., deviations in manufacturing accuracy and installation accuracy.

In addition, in each of the drawings to be referred to below, in order to facilitate ease of understanding the descriptions, an orthogonal coordinate system may be defined in which an X-axis direction, a Y-axis direction, and a Z-axis direction are orthogonal to one another, and the Z-axis positive direction is a vertically upward direction. In addition, a direction of rotation about a vertical axis may be referred to as a θ direction.

In the related art, there is known a liquid processing apparatus which circulates a processing liquid for a substrate such as a semiconductor wafer (hereinafter also referred to as a wafer) through a circulation line and supplies the processing liquid to a processor via a branch line branching from the circulation line. The circulation line of the liquid processing apparatus is provided with a filter which removes foreign substances from the processing liquid. In addition, a technique is known in which the processing liquid flowing through the circulation line is heated to a desired temperature by a heating mechanism.

In the circulation line, the circulation of the processing liquid may be stopped for maintenance or the like. When the circulation of the processing liquid is restarted after the stop of the circulation, the processing liquid is heated by the heating mechanism. At this time, the filter thermally expands due to the influence of a change in the temperature of the processing liquid. This may cause particles trapped in the filter to be released from the filter, resulting in contamination of the processing liquid in the circulation line.

Therefore, a technique capable of reducing the contamination of the processing liquid in the circulation line is needed.

### First Embodiment

### <Overview of Substrate Processing System>

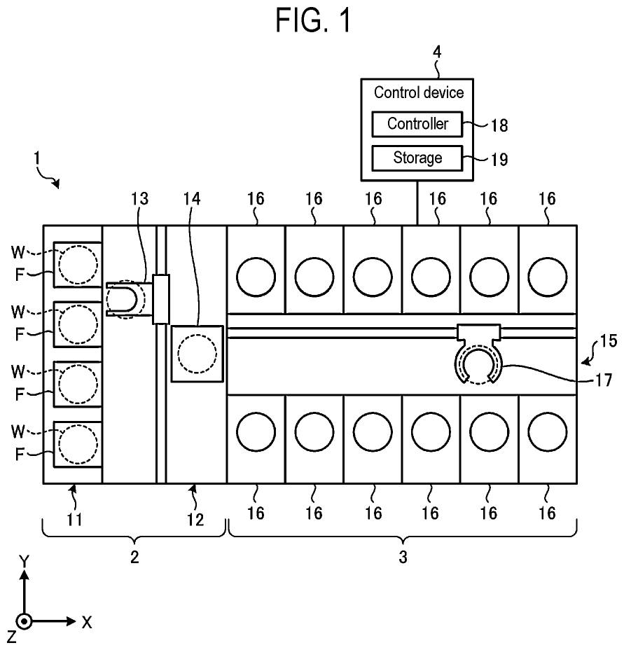

First, a schematic configuration of a substrate processing system 1 according to a first embodiment will be described with reference to FIG. 1. FIG. 1 is a diagram showing the schematic configuration of the substrate processing system 1 according to the first embodiment.

As shown in FIG. 1, the substrate processing system 1 includes a loading/unloading station 2 and a processing station 3. The loading/unloading station 2 and the processing station 3 are provided adjacent to each other.

The loading/unloading station 2 includes a FOUP stage 11 and a transferer 12. A plurality of FOUPs Fs is placed on the FOUP stage 11. Each of the plurality of FOUPs Fs accommodates a plurality of substrates, that is, semiconductor wafers W (hereinafter referred to as wafers W) in this embodiment, in a horizontal posture.

The transferer 12 is provided adjacent to the FOUP stage 11, and includes a substrate transfer device 13 and a deliverer 14 provided therein. The substrate transfer device 13 includes a wafer holding mechanism configured to hold the wafer W. The substrate transfer device 13 is movable in horizontal and vertical directions and rotatable about a vertical axis, and is configured to transfer the wafer W between the FOUP F and the deliverer 14 using the wafer holding mechanism.

The processing station 3 is provided adjacent to the transferer 12. The processing station 3 includes a transferer 15 and a plurality of processing units 16. The plurality of processing units 16 are provided side by side on both sides of the transferer 15.

The transferer 15 includes a substrate transfer device 17 provided therein. The substrate transfer device 17 includes a wafer holding mechanism configured to hold the wafer W. The substrate transfer device 17 is movable in the horizontal and vertical directions and rotatable about a vertical axis, and is configured to transfer the wafer W between the deliverer 14 and the processing unit 16 using the wafer holding mechanism.

The processing unit 16 is an example of a liquid processor, and is configured to perform a predetermined liquid processing on the wafer W transferred by the substrate transfer device 17.

Further, the substrate processing system 1 includes a control device 4. The control device 4 is, for example, a computer, and includes a controller 18 and a storage 19. The storage 19 stores programs for controlling various processes executed in the substrate processing system 1. The controller 18 controls the operation of the substrate processing system 1 by reading and executing the programs stored in the storage 19.

The program may be recorded in a computer-readable storage medium and installed from the storage medium in the storage 19 of the control device 4. Examples of the computer-readable storage medium include a hard disk (HD), a flexible disk (FD), a compact disk (CD), a magnet optical disk (MO), and a memory card.

In the substrate processing system 1 configured as above, first, the substrate transfer device 13 in the loading/unloading station 2 takes out the wafer W from the FOUP F placed on the FOUP stage 11, and places the same on the deliverer 14. Thereafter, the wafer W placed on the deliverer 14 is taken out from the deliverer 14 by the substrate transfer device 17 in the processing station 3, and is loaded into the processing unit 16.

The wafer W loaded into the processing unit 16 is processed by the processing unit 16. Thereafter, the wafer W is unloaded from the processing unit 16 by the substrate transfer device 17 and placed on the deliverer 14. Then, the processed wafer W placed on the deliverer 14 is returned to the FOUP F of the FOUP stage by the substrate transfer device 13.

### <Overview of Processing Unit>

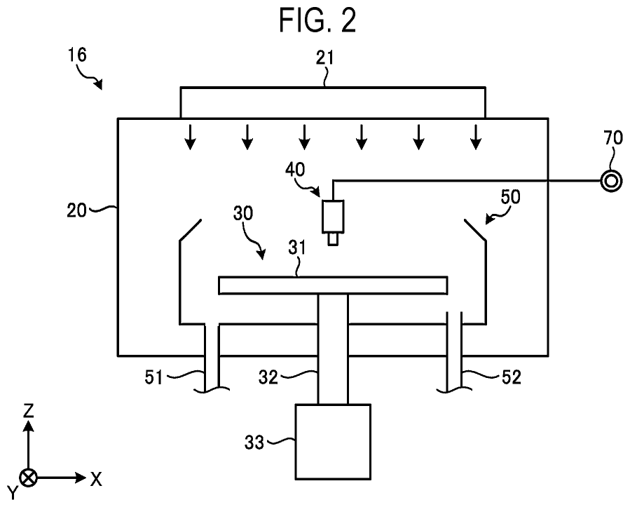

Next, an overview of the processing unit 16 will be described with reference to FIG. 2. FIG. 2 is a schematic diagram showing a configuration of the processing unit 16 according to the first embodiment. The processing unit 16 includes a chamber 20, a substrate processor 30, a liquid supplier 40, and a collection cup 50.

The chamber 20 accommodates the substrate processor 30, the liquid supplier 40, and the collection cup 50. A fan filter unit (FFU) 21 is provided on a ceiling of the chamber 20. The FFU 21 forms a down-flow inside the chamber 20.

The substrate processor 30 includes a holder 31, a support 32, and a driver 33, and performs liquid processing on the placed wafer W. The holder 31 holds the wafer W (see FIG. 1) horizontally. The support 32 is a member extending in the vertical direction. A base end of the support 32 is rotatably supported by the driver 33, and a tip end thereof supports the holder 31 horizontally. The driver 33 rotates the support 32 about a vertical axis.

The substrate processor 30 rotates the holder 31 supported by the support 32 by rotating the support 32 using the driver 33. Thus, the wafer W held by the holder 31 is rotated.

The liquid supplier 40 supplies a processing liquid to the wafer W. The liquid supplier 40 is connected to a processing liquid source 70. The liquid supplier 40 includes a plurality of nozzles. The plurality of nozzles is provided to correspond to, for example, a plurality of types of processing liquid. The plurality of nozzles discharges, onto the wafer W, the plurality of types of processing liquid respectively supplied from the plurality of processing liquid sources 70.

The collection cup 50 is disposed to surround the holder 31, and is configured to collect the processing liquid scattered from the wafer W due to the rotation of the holder 31. A drain port 51 is formed in a bottom of the collection cup 50. The processing liquid collected by the collection cup 50 is discharged from the drain port 51 outward of processing unit 16.

Further, an exhaust port 52 is formed in the bottom of the collection cup 50 to exhaust the gas supplied from the FFU 21 outward of the processing unit 16.

### <Overview of Processing Liquid Source>

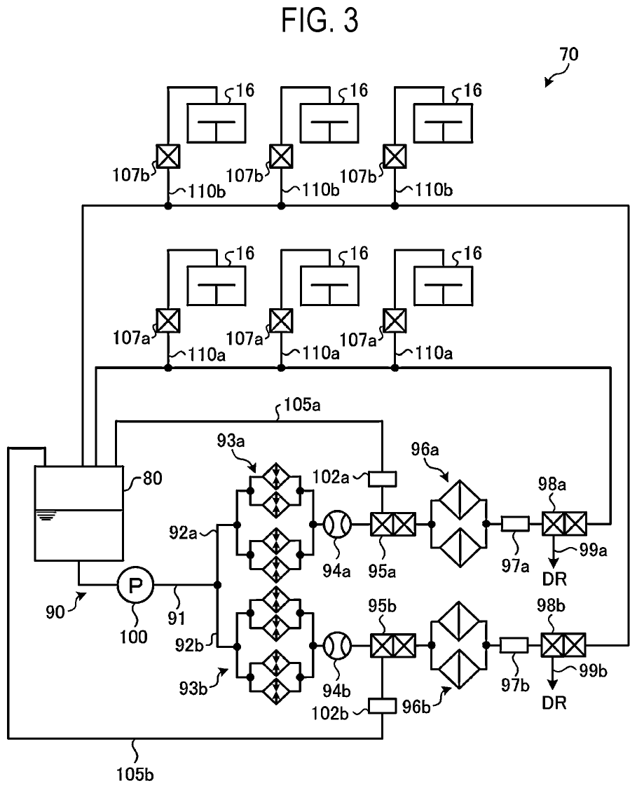

Next, a schematic configuration of the processing liquid source 70 provided in the substrate processing system 1 will be described with reference to FIG. 3. FIG. 3 is a diagram showing the schematic configuration of the processing liquid source 70 according to the embodiment. The processing liquid source 70 is an example of a liquid supply device.

As shown in FIG. 3, the processing liquid source 70 included in the substrate processing system 1 supplies the processing liquid to the plurality of processing units 16. In the first embodiment, for example, the processing liquid source 70 shown in FIG. 3 is provided for each of the plurality of types of processing liquids.

As shown in FIG. 3, the processing liquid source 70 includes a tank 80, a circulation line 90 (an example of a processing liquid line), and a pump 100. The tank 80 stores the processing liquid. The processing liquid is, for example, IPA (isopropyl alcohol). The processing liquid of the present disclosure is not limited to IPA, and various types of chemical liquids may be used.

The circulation line 90 returns the processing liquid sent from the tank 80 to the tank 80. The circulation line 90 includes a main line 91 on the upstream side and a plurality of (two in this embodiment) branch lines 92a and 92b (hereinafter also referred to as a “first branch line 92a” and a “second branch line 92b”) on the downstream side.

Hereinafter, in this specification, the last letter of the reference numeral given to components belonging to the first branch line 92a is “a”, and the last letter of the reference numeral given to components belonging to the second branch line 92b is “b”. The components belonging to the first branch line 92a and the components belonging to the second branch line 92b are the same or substantially the same. When it is not necessary to distinguish between the components belonging to the first branch line 92a and the components belonging to the second branch line 92b, the last letters “a” and “b” may be omitted (for example, 93a and 93b may be written as 93).

The pump 100 is provided in the main line 91. The pump 100 forms a circulating flow of the processing liquid in the circulation line 90.

The main line 91 branches into the first branch line 92a and the second branch line 92b at a branch (branch point) set at its downstream end, that is, downstream of the pump 100. The processing liquid flowing out of the tank 80 passes through the main line 91, then flows into the first branch line 92a and the second branch line 92b, and returns to the tank 80 via the first branch line 92a and the second branch line 92b.

That is, in the processing liquid source 70 according to the first embodiment, a driving force generated by the pump 100 causes the processing liquid to circulate in both the first branch line 92a and the second branch line 92b of the circulation line 90. This makes it possible to reduce the number of pumps and the cost of the processing liquid source, compared to a case in which a pump is provided in each of the first branch line 92a and the second branch line 92b.

The first branch line 92a includes a first heating mechanism 93a, a first flowmeter 94a, a third valve 95a, a first filter 96a, a first circulation temperature sensor 97a (an example of a first temperature sensor), and a first valve 98a which are arranged sequentially from the upstream side. The second branch line 92b includes a second heating mechanism 93b, a second flowmeter 94b, a fourth valve 95b, a second filter 96b, a second circulation temperature sensor 97b (an example of the first temperature sensor), and a second valve 98b which are arranged sequentially from the upstream side.

The heating mechanisms 93 (the first heating mechanism 93a and the second heating mechanism 93b) heat the processing liquid passing through the heating mechanisms 93. The controller 18 may adjust a temperature of the processing liquid by controlling an amount of heat applied to the processing liquid by the heating mechanisms 93. Each of the first heating mechanism 93a and the second heating mechanism 93b includes a plurality of heating modules arranged in parallel. The heating mechanisms 93 are controlled by the controller 18.

The number of heating modules belonging to one heating mechanism 93 may be determined in consideration of a temperature control capacity required for the heating mechanism 93 and an allowable pressure drop in the heating mechanism 93. In the first embodiment, as shown in FIG. 3, each of the first heating mechanism 93a and the second heating mechanism 93b includes four heating modules arranged in parallel.

The flowmeters 94 (the first flowmeter 94a and the second flowmeter 94b) measure a flow rate of the circulating flow of the processing liquid formed in the circulation line 90. Measurement results obtained by the flowmeters 94 are outputted to the controller 18.

The valves 95 (the third valve 95a and the fourth valve 95b) switch a destination of the processing liquid. Specifically, the first branch circulation line 105a connected to the tank 80 branches from the third valve 95a. The first branch circulation line 105a returns the processing liquid sent from the tank 80 to the first branch line 92a to the tank 80. The third valve 95a switches the destination of the processing liquid in the first branch line 92a between the first branch circulation line 105a and the first filter 96a. For example, when the controller 18 controls the third valve 95a to set the destination of the processing liquid to the first branch circulation line 105a, the processing liquid sent from the tank 80 returns to the tank 80 via the third valve 95a. Further, for example, when the controller 18 controls the third valve 95a to set the destination of the processing liquid to the first filter 96a, the processing liquid sent from the tank 80 flows into the first filter 96a via the third valve 95a. In addition, the controller 18 may also control the third valve 95a such that the processing liquid flows into both the first branch circulation line 105a and the first filter 96a.

The first branch circulation line 105a is provided with a first branch temperature sensor

102a (an example of a second temperature sensor) for detecting the temperature of the processing liquid flowing through the first branch circulation line 105a. Detection results obtained by the first branch temperature sensor 102a are outputted to the controller 18.

Similarly, the second branch circulation line 105b connected to the tank 80 branches from the fourth valve 95b. The second branch circulation line 105b returns the processing liquid sent from the tank 80 to the second branch line 92b to the tank 80. The fourth valve 95b switches the destination of the processing liquid in the second branch line 92b between the second branch circulation line 105b and the second filter 96b. For example, when the controller 18 controls the fourth valve 95b to set the destination of the processing liquid to the second branch circulation line 105b, the processing liquid sent from the tank 80 returns to the tank 80 via the fourth valve 95b. Further, for example, when the controller 18 controls the fourth valve 95b to set the destination of the processing liquid to the second filter 96b, the processing liquid sent from the tank 80 flows into the second filter 96b via the fourth valve 95b. The controller 18 may also control the fourth valve 95b such that the processing liquid flows into both the second branch circulation line 105b and the second filter 96b.

The second branch circulation line 105b is provided with a second branch temperature sensor 102b (an example of the second temperature sensor) for detecting the temperature of the processing liquid flowing through the second branch circulation line 105b. Detection results obtained by the second branch temperature sensor 102b are outputted to the controller 18.

As described above, the processing liquid source 70 according to the first embodiment includes the first branch circulation line 105a and the second branch circulation line 105b. As a result, in a process of forming a circulating flow of the processing liquid in the circulation line 90 again after the circulation of the processing liquid has been stopped for maintenance or the like, by heating the processing liquid while forming the circulating flow of the processing liquid flowing through the first branch circulation line 105a or the second branch circulation line 105b, it is possible to perform a process of increasing the temperature of the processing liquid without passing the processing liquid through the filter 96.

Therefore, according to the first embodiment, it is possible to reduce contamination of the processing liquid caused by the particles released from the filter 96 as the temperature of the processing liquid increases. Further, in the first embodiment, since the processing liquid does not flow through the filter 96 in which particles are trapped, it is possible to reduce the contamination of the processing liquid during the temperature increasing process.

The filters 96 (the first filter 96a and the second filter 96b) remove contaminants such as particles contained in the processing liquid passing through the filters 96. Each of the first filter 96a and the second filter 96b may include a plurality of filter modules arranged in parallel. The number of filter modules belonging to one filter 96 may be determined in consideration of a filtering capacity required for the filters 96 and an allowable pressure drop in the filters 96. In the first embodiment, as shown in FIG. 3, each of the first filter 96a and the second filter 96b is constituted with two filter modules arranged in parallel.

The circulation temperature sensors 97 (the first circulation temperature sensor 97a and the second circulation temperature sensor 97b) detect the temperature of the processing liquid flowing through the circulation line 90. Detection results obtained by the circulation temperature sensors 97 are outputted to the controller 18.

The circulation temperature sensors 97 do not necessarily need to detect the temperature of the processing liquid flowing through the circulation line 90. For example, the circulation temperature sensors 97 may be provided on the filters 96, the circulation line 90 (the first branch line 92a and the second branch line 92b), and the drain line 99, to detect the temperatures of the filters 96, the circulation line 90, and the drain line 99.

Further, although the example has been described in which two temperature sensors, that is, the first circulation temperature sensor 97a and the second circulation temperature sensor 97b are provided, the present disclosure is not limited thereto. Only one of the two temperature sensors may be provided.

The valves 98 (the first valve 98a and the second valve 98b) switch the destination of the processing liquid. Specifically, the first drain line 99a connected to the drainer DR branches from the first valve 98a. The first drain line 99a drains the processing liquid flowing into the first branch line 92a. The first valve 98a switches the destination of the processing liquid in the first branch line 92a between the first drain line 99a and the first branch line 92a. For example, when the controller 18 controls the first valve 98a to set the destination of the processing liquid to the first drain line 99a, the processing liquid sent from the tank 80 is drained via the first valve 98a. Further, for example, when the controller 18 controls the first valve 98a to set the destination of the processing liquid to the first branch line 92a, the processing liquid sent from the tank 80 flows into the first branch line 92a via the first valve 98a. The controller 18 may also control the first valve 98a such that the processing liquid flows into both the first branch line 92a and the first drain line 99a.

Similarly, the second drain line 99b connected to the drainer DR branches from the second valve 98b. The second drain line 99b drains the processing liquid flowing into the second branch line 92b. The second valve 98b switches the destination of the processing liquid in the second branch line 92b between the second drain line 99b and the second branch line 92b. For example, when the controller 18 controls the second valve 98b to set the destination of the processing liquid to the second drain line 99b, the processing liquid sent from the tank 80 is drained via the second valve 98b. Further, for example, when the controller 18 controls the second valve 98b to set the destination of the processing liquid to the second branch line 92b, the processing liquid sent from the tank 80 flows into the second branch line 92b via the second valve 98b. The controller 18 may also control the second valve 98b such that the processing liquid flows into both the second branch line 92b and the second drain line 99b.

A plurality of first supply lines 110a is connected to the first branch line 92a located downstream of the first valve 98a. One end of the first supply line 110a is connected to the first branch line 92a, and the other end thereof is connected to the processing unit 16. The first supply line 110a supplies the processing liquid flowing through the first branch line 92a to the processing unit 16. A fifth valve 107a for opening and closing the first supply line 110a is provided in the middle of the first supply line 110a.

A plurality of second supply lines 110b is connected to the second branch line 92b located downstream of the second valve 98b. One end of the second supply line 110b is connected to the second branch line 92b, and the other end thereof is connected to the processing unit 16. The second supply line 110b supplies the processing liquid flowing through the second branch line 92b to the processing unit 16. A sixth valve 107b for opening and closing the second supply line 110b is provided in the middle of the second supply line 110b.

FIG. 3 shows an example in which three first supply lines 110a are connected to the first branch line 92a. However, the number of first supply lines 110a connected to the first branch line 92a is not limited to three. Similarly, the number of second supply lines 110b connected to the second branch line 92b is not limited to three.

In addition, in the above, the example has been described in which the first valve 98a, the second valve 98b, the third valve 95a, and the fourth valve 95b are switching valves for switching the destination of the processing liquid. However, the first valve 98a, the second valve 98b, the third valve 95a, and the fourth valve 95b do not necessarily need to be switching valves. For example, the first valve 98a may be constituted with two opening/closing valves, that is, an opening/closing valve provided in the first drain line 99a and an opening/closing valve provided in the first branch line 92a downstream of the first drain line 99a. This holds true with respect to the second valve 98b, the third valve 95a, and the fourth valve 95b.

In the substrate processing system 1 configured as above, in the process of allowing the processing liquid to flow through the circulation line 90 again after the flow of the processing liquid has been stopped for maintenance or the like, contaminants such as particles trapped in the filters 96 may be discharged together with the processing liquid by performing an operation of initially draining a certain amount of the processing liquid from the drain line 99 (hereinafter referred to as “initial dump process”).

In a case in which an amount of processing liquid discharged in the initial dump operation (hereinafter referred to as the “initial dump amount”) is not clear, more processing liquid than necessary may be discharged from the drain line 99.

Under these circumstances, the present disclosers have found a relationship between the temperature of the processing liquid flowing through the drain line 99 and the amount of contaminants such as particles contained in the processing liquid (hereinafter referred to as the “particle amount”).

Specifically, the present disclosers have found that the temperature of the processing liquid flowing through the drain line 99 increases along with an increase in the initial dump amount, and further that the temperature stabilizes when the initial dump amount reaches a certain amount. Specifically, the present disclosers measured the temperature of the processing liquid when the initial dump amount reached 2 L, 4 L, 8 L, 12 L, and 24 L. As a result, the temperature of the processing liquid was about 45 degrees C. when the initial dump amount reached 2 L, and about 54 degrees C. when the initial dump amount reached 4 L, whereas the temperature of the processing liquid hardly changed after the initial dump amount exceeded 4 L.

The present disclosers also measured the amount of particles when the initial dump amount reached 2 L, 4 L, 8 L, 12 L, and 24 L. As a result, the amount of particles when the initial dump amount is 2 L was greater than that when the initial dump amount is 4 L, 8 L, 12 L, and 24 L, whereas the amount of particles when the initial dump amount is 4 L, 8 L, 12 L, and 24 L was approximately the same.

From these results, the substrate processing system 1 according to the first embodiment determines whether or not to drain the processing liquid flowing through the circulation line 90 from the drain line 99 based on the temperature of the processing liquid flowing through the circulation line 90. By performing such a determination, it is possible to optimize the initial dump amount. That is, since the initial dump operation may be ended at a stage where the amount of particles has sufficiently decreased, it is possible to appropriately suppress contamination of the processing liquid in the circulation line 90. In addition, by ending the initial dump operation at a timing when no change in the amount of particles is observed, it is possible to suppress unnecessary discharge of the processing liquid. Details of the determination operation will be described later.

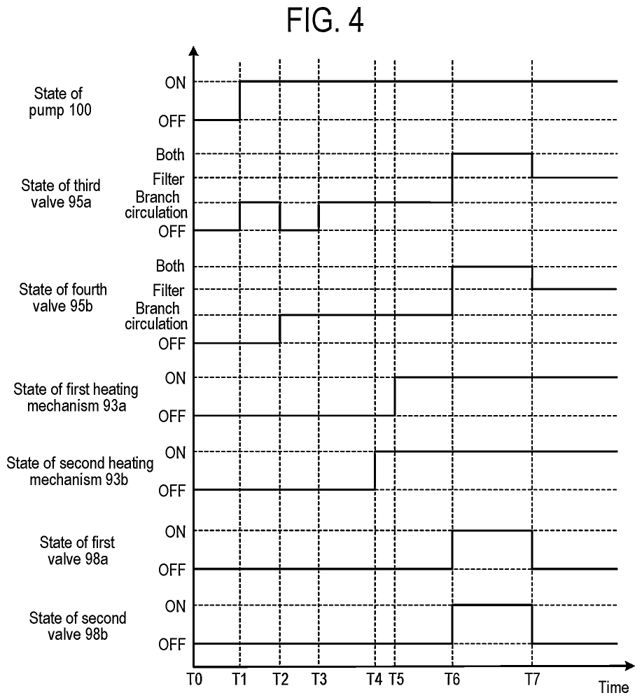

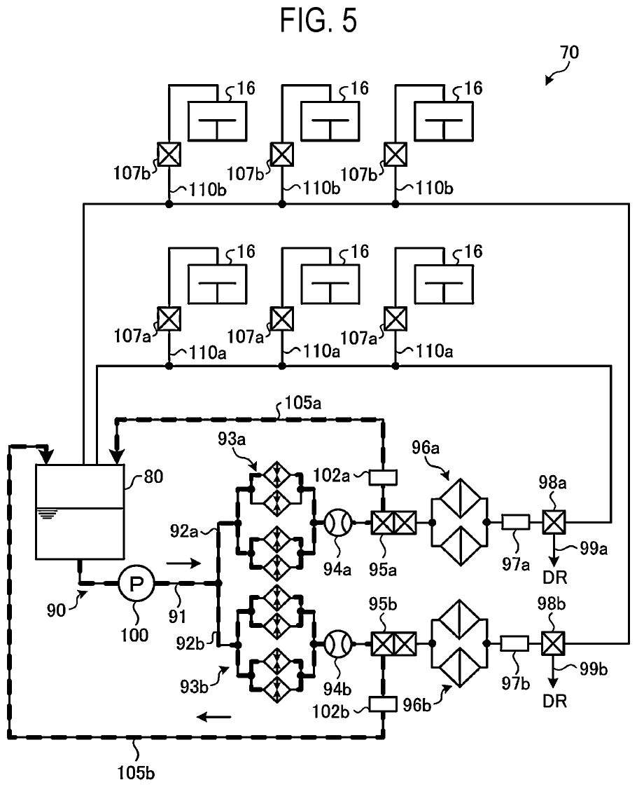

Next, an example of an operation of the substrate processing system 1 according to the first embodiment will be described with reference to FIG. 4. FIG. 4 is a diagram showing an example of state transitions of the pump 100, the first valve 98a to the fourth valve 95b, the first heating mechanism 93a, and the second heating mechanism 93b. FIGS. 5 to 7 are schematic diagrams showing an example of an operation of the processing liquid source 70 according to the first embodiment. A process shown in FIG. 4 is an example of the operation when starting the circulation of the processing liquid again after the circulation of the processing liquid in the circulation line 90 has stopped for maintenance or the like.

First, the controller 18 operates the pump 100, which has been stopped, to pump the processing liquid from the tank 80 to the circulation line 90 (time T1). At the same time, the controller 18 controls the third valve 95a such that the processing liquid flows into the first branch circulation line 105a. As a result, the processing liquid sent from the tank 80 flows into the first branch circulation line 105a via the third valve 95a and circulates to return to the tank 80.

Subsequently, the controller 18 closes the third valve 95a to stop the flow of the processing liquid to the first branch circulation line 105a (time T2). At the same time, the controller 18 controls the fourth valve 95b such that the processing liquid flows into the second branch circulation line 105b. As a result, the processing liquid sent from the tank 80 flows into the second branch circulation line 105b via the fourth valve 95b and circulates to return to the tank 80.

Subsequently, the controller 18 controls the third valve 95a such that the processing liquid flows into the first branch circulation line 105a (time T3). As a result, the processing liquid sent from the tank 80 flows into the first branch circulation line 105a and the second branch circulation line 105b, and circulates to return to the tank 80 (see FIG. 5).

Subsequently, the controller 18 determines whether or not a circulation flow rate of the processing liquid flowing through the first branch circulation line 105a and the second branch circulation line 105b is stable based on measurement values obtained by the first flowmeter 94a and the second flowmeter 94b. Specifically, when the measurement value by the first flowmeter 94a falls within a preset threshold range, the controller 18 determines that the circulation flow rate of the processing liquid is stable, and controls the first heating mechanism 93a to start heating. Similarly, when the measurement value by the second flowmeter 94b falls within a preset threshold range, the controller 18 determines that the circulation flow rate of the processing liquid in the second branch line 92b is stable, and controls the second heating mechanism 93b to start heating. For example, as shown in FIG. 4, when the measurement value by the second flowmeter 94b is determined to fall within the threshold range, the controller 18 operates the second heating mechanism 93b (time T4). Then, when the measurement value by the first flowmeter 94a is determined to fall within the threshold range, the controller 18 operates the first heating mechanism 93a (time T5).

Subsequently, the controller 18 determines whether or not the temperature of the processing liquid flowing through the first branch circulation line 105a and the second branch circulation line 105b is stable based on the detection results obtained by the first branch temperature sensor 102a and the second branch temperature sensor 102b. Specifically, when the measurement value by the first branch temperature sensor 102a falls within a preset threshold range in a preset monitoring time width, the controller 18 determines that the temperature of the processing liquid in the first branch circulation line 105a is stable. Similarly, when the measurement value of the second branch temperature sensor 102b falls within a preset threshold range in a preset monitoring time width, the controller 18 determines that the temperature of the processing liquid in the second branch circulation line 105b is stable.

When the temperatures of the processing liquid in the first branch line 92a and the second branch line 92b are determined to be stable, the controller 18 controls the first valve 98a to the fourth valve 95b such that the processing liquid flows into the drain line 99 while circulating in the first branch circulation line 105a and the second branch circulation line 105b. For example, as shown in FIG. 4, when the measurement values by the first branch temperature sensor 102a and the second branch temperature sensor 102b are determined to fall within the preset threshold range in the preset monitoring time width, the controller 18 controls the third valve 95a and the fourth valve 95b such that the processing liquid flows into both the filter 96 and the branch circulation line 105 (time T6).

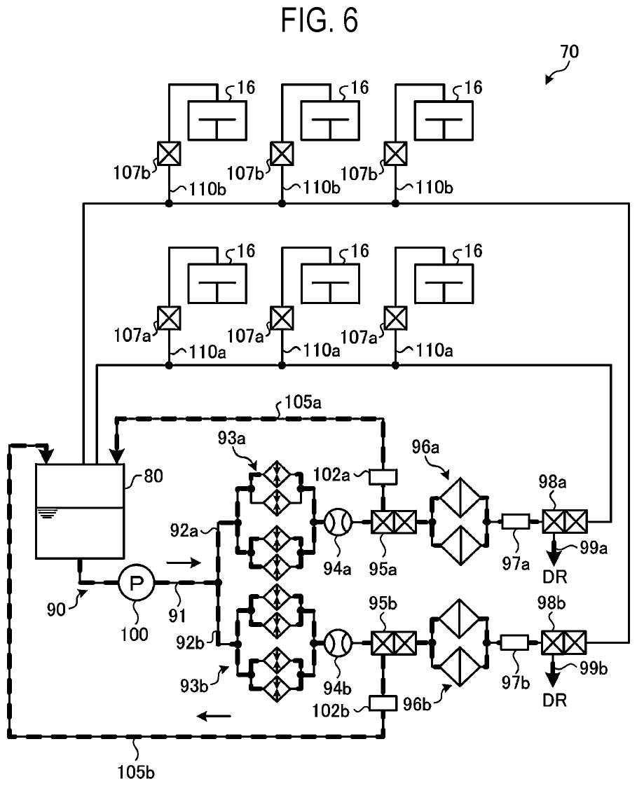

At the same time, the controller 18 controls the first valve 98a and the second valve 98b such that the processing liquid flows into the first drain line 99a and the second drain line 99b. As a result, the processing liquid sent from the tank 80 flows into the first filter 96a and the second filter 96b and is drained from the drain line 99, while flowing into the first branch circulation line 105a or the second branch circulation line 105b and circulating back to the tank 80 (see FIG. 6).

Subsequently, the controller 18 determines whether or not to drain the processing liquid from the drain line 99 based on the detection results by the first circulation temperature sensor 97a and the second circulation temperature sensor 97b. Specifically, when the measurement values by the first circulation temperature sensor 97a and the second circulation temperature sensor 97b are equal to or greater than a threshold value, the controller 18 controls the first valve 98a to the fourth valve 95b to switch the destination of the processing liquid from the drain line 99 to the supply line 110.

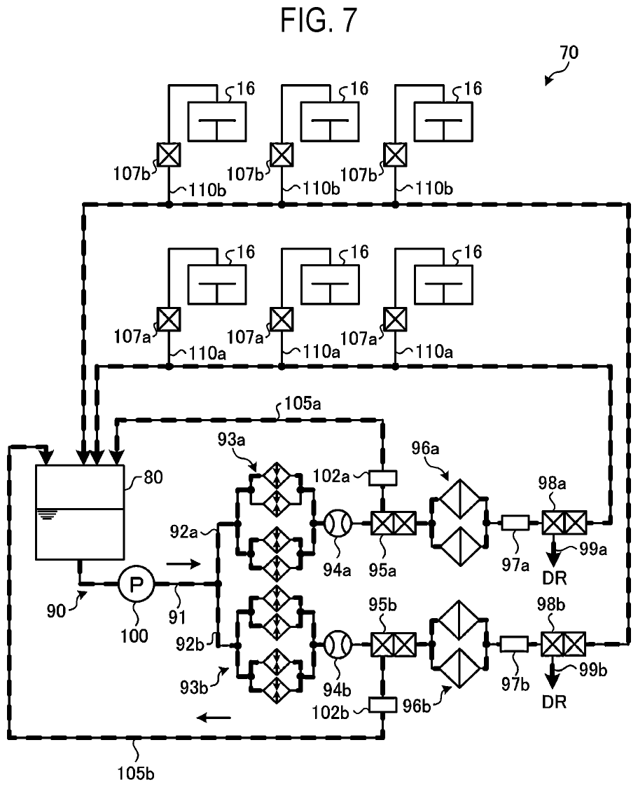

For example, as shown in FIG. 4, when the measurement values by both the first circulation temperature sensor 97a and the second circulation temperature sensor 97b are equal to or greater than the threshold value, the controller 18 controls the third valve 95a and the fourth valve 95b to switch the destination of the processing liquid to the filter 96 (time T7). At the same time, the controller 18 controls the first valve 98a and the second valve 98b to switch the destination of the processing liquid to the supply line 110. As a result, the processing liquid sent from the tank 80 flows into the first branch line 92a and the second branch line 92b and returns to the tank 80 (see FIG. 7). In addition, when the fifth valve 107a or the sixth valve 107b remains open, the processing liquid is supplied from the supply line 110 to the processing unit 16.

In this way, the controller 18 determines whether or not to drain the processing liquid from the drain line 99 based on the detection results by the first circulation temperature sensor 97a and the second circulation temperature sensor 97b. Specifically, when the temperature of the processing liquid flowing through the circulation line 90 is determined to be equal to or higher than the threshold value based on the detection results by the first circulation temperature sensor 97a and the second circulation temperature sensor 97b, the controller 18 controls the first valve 98a and the second valve 98b to switch the destination of the processing liquid from the drain line 99 to the supply line 110.

In the above, the example has been described in which the destination of the processing liquid is switched from the drain line 99 to the supply line 110 when the temperature of the processing liquid flowing through the circulation line 90 is equal to or higher than the threshold value. However, the present disclosure is not limited thereto. For example, when the temperature of the processing liquid flowing through the circulation line 90 becomes equal to or higher than the threshold value, the processing liquid may be continuously drained until a predetermined period of time elapses. Specifically, when the temperature of the processing liquid flowing through the circulation line 90 becomes equal to or higher than the threshold value, the controller 18 controls the first valve 98a and the second valve 98b to switch the destination of the processing liquid to the drain line 99 and the supply line 110. As a result, the processing liquid sent from the tank 80 is drained from the drain line 99 at a certain amount while flowing into the branch line 92. Thereafter, the controller 18 switches the destination of the processing liquid to the supply line 110 when a predetermined period time elapses.

After the processing liquid heated by the heating mechanism 93 starts to be drained (time T6), the temperature of the processing liquid flowing through the circulation line 90 gradually increases. Thereafter, when the temperature of the processing liquid reaches or exceeds a threshold value, most of the particles trapped in the filter 96 flow out. This lessens the likelihood of contaminating the interior of the circulation line 90. By stopping the drain of the processing liquid at that point (time T7) and starting the circulation of the processing liquid in the circulation line 90, it is possible to minimize the amount of processing liquid to be drained. In other words, the controller 18 controls whether or not to drain the processing liquid based on the temperature of the processing liquid flowing through the circulation line 90. Thus, the amount of processing liquid to be drained may be made appropriate.

Further, the controller 18 controls the pump 100, the first heating mechanism 93a, and the second heating mechanism 93b to heat the processing liquid while the processing liquid circulates in the first branch circulation line 105a and the second branch circulation line 105b (time T5 to time T7).

As described above, the controller 18 controls the operation of the substrate processing system such that the processing liquid is heated while circulating in the first branch circulation line 105a and the second branch circulation line 105b. Thus, it is possible to efficiently heat the processing liquid in a short period of time compared to a case where the processing liquid is heated while totally circulating in the circulation line 90.

Further, when the temperatures of the processing liquid flowing through the first branch circulation line 105a and the second branch circulation line 105b is determined to be stable based on the detection results by the first branch temperature sensor 102a and the second branch temperature sensor 102b, the controller 18 controls the pump 100 to send the processing liquid to the filter 96 (time T6). Thus, it is possible to send the processing liquid to the circulation line 90 after the temperature of the processing liquid is stable.

Further, the controller 18 controls the pump 100, the first valve 98a, and the second valve 98b to send the processing liquid circulating in the first branch circulation line 105a and the second branch circulation line 105b to the first filter 96a and the second filter 96b, so that the processing liquid passed through the first filter 96a and the second filter 96b is drained via the first drain line 99a and the second drain line 99b (time T6 to time T7).

Therefore, the processing liquid may be drained when particles trapped in the first filter 96a and the second filter 96b are released due to a change in the temperature of the processing liquid. This makes it possible to reduce contamination of the processing liquid in the circulation line 90 by the particles.

When the measurement values obtained by the first flowmeter 94a and the second flowmeter 94b are determined to fall within their respective threshold ranges, the controller 18 controls the third valve 95a to switch the destination of the processing liquid in the first branch circulation line 105a from the first branch circulation line 105a to the first filter 96a, and controls the fourth valve 95b to switch the destination of the processing liquid in the second branch circulation line 105b from the second branch circulation line 105b to the second filter 96b. This makes it possible to send the processing liquid to the first filter 96a and the second filter 96b after the flow rate of the processing liquid is stable (time T4 and time T5).

Further, the controller 18 starts to send the processing liquid to the first branch circulation line 105a (time T1), and then starts to send the processing liquid to the second branch circulation line 105b (time T2). By sending the processing liquid line by line in this way, the processing liquid is more likely to become full than when the processing liquid is sent to both lines at the same time.

After the processing liquid is drained from the first drain line 99a and the second drain line 99b, the controller 18 controls the first valve 98a and the second valve 98b to send the processing liquid to the first branch line 92a and the second branch line 92b and to return the processing liquid to the tank 80 (time T7). This makes it possible to reduce the contamination of the interior of the tank 80 caused when the particles trapped by the filter 96 inside the tank 80 flow into the tank 80.

Further, the controller 18 controls the operation of the substrate processing system such that the processing liquid circulates in the first branch circulation line 105a and the second branch circulation line 105b (time T6 to time T7) while circulating the processing liquid in the circulation line 90. This makes it possible to prevent the processing liquid from staying in the first branch circulation line 105a and the second branch circulation line 105b while the processing liquid is circulating in the circulation line 90.

As described above, the controller 18 determines whether or not to drain the processing liquid from the drain line 99 based on the detection results obtained by the first circulation temperature sensor 97a and the second circulation temperature sensor 97b. This makes it possible to optimize the amount of processing liquid to be drained while reducing contamination of the processing liquid flowing through the circulation line 90.

In the above, the example has been described in which the processing liquid being heated is discharged to the drainer DR via the drain line 99, and then the circulating flow of the processing liquid passing through the circulation line 90 is formed. However, the present disclosure is not limited thereto.

For example, the controller 18 may repeatedly perform a process of, before starting the circulation of the processing liquid in the circulation line 90, heating the processing liquid while circulating the processing liquid in the first branch circulation line 105a and the second branch circulation line 105b (time T4 and time T5), sending the processing liquid circulating in the first branch circulation line 105a and the second branch circulation line 105b to the filter 96, and draining the processing liquid via the drain line 99 (time T6 and time T7).

With this configuration, it is possible to flow a larger number of particles trapped in the filter 96 toward the downstream side, thus further reducing contamination of the processing liquid in the circulation line 90.

### Second Embodiment

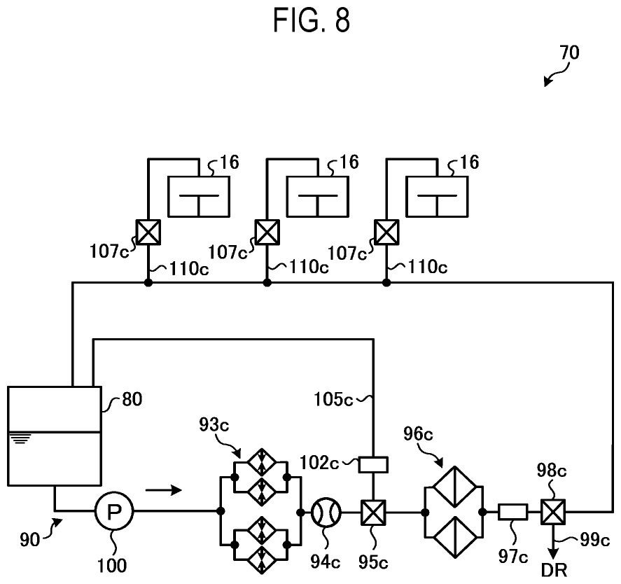

FIG. 8 is a diagram showing a schematic configuration of a processing liquid source 70 according to a second embodiment. Although in the above-described first embodiment, the example in which the circulation line 90 branches into the first branch line 92a and the second branch line 92b has been described, the present disclosure is not limited thereto. The circulation line 90 does not have to include such branch lines.

As shown in FIG. 8, the processing liquid source 70 includes a circulation line 90 through which the processing liquid sent from the tank 80 returns to the tank 80. The circulation line 90 includes a pump 100, a heating mechanism 93c, a flowmeter 94c, a valve 95c, a filter 96c, a circulation temperature sensor 97c, and a valve 98c, which are arranged sequentially from the upstream side.

A branch circulation line 105c connected to the tank 80 branches from the valve 95c. A branch temperature sensor 102c for detecting a temperature of the processing liquid flowing through the branch circulation line 105c is provided in the branch circulation line 105c. A drain line 99c connected to a drain part DR branches from the valve 98c.

In this case as well, at time T7 in FIG. 4, whether or not to drain the processing liquid from the drain line 99c is determined based on the detection result by the circulation temperature sensor 97c. Specifically, when the measurement value by the circulation temperature sensor 97c is equal to or higher than a threshold value, the controller 18 controls the valves 98c and 95c to switch the destination of the processing liquid from the drain line 99c to the supply line 110c. This makes it possible to optimize the amount of processing liquid to be drained while reducing contamination of the processing liquid flowing through the circulation line 90.

### Third Embodiment

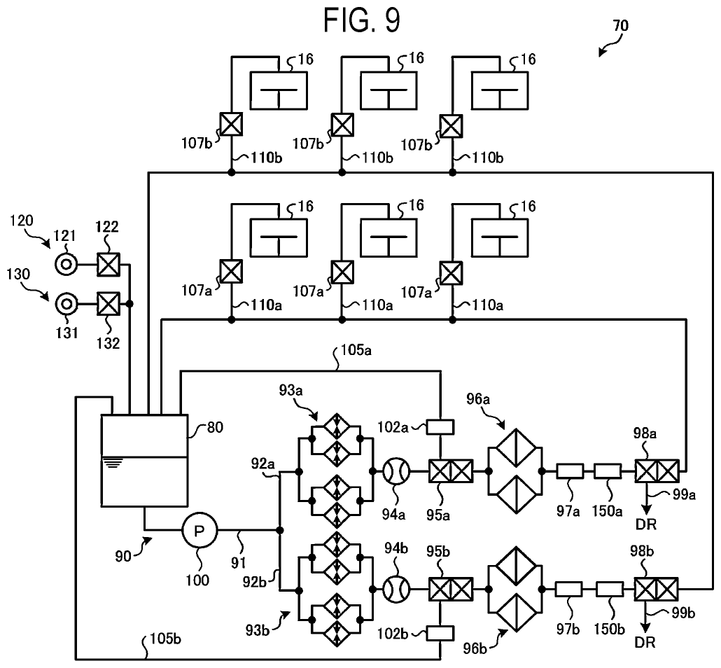

FIG. 9 is a diagram showing a schematic configuration of a processing liquid source 70 according to a third embodiment. The processing liquid source 70 according to the third embodiment differs from the processing liquid source 70 according to the first embodiment in that the processing liquid source 70 according to the third embodiment includes a cleaning liquid supplier 120 and a new liquid supplier 130. Therefore, in the following example, the same components as those in the above-described embodiments will be designated by like reference numerals, and detailed descriptions thereof will be omitted.

The cleaning liquid supplier 120 supplies a cleaning liquid for the filter 96 to the tank 80. The cleaning liquid supplier 120 includes a cleaning liquid source 121 and a seventh valve 122. The cleaning liquid for the filter 96 is supplied from the cleaning liquid source 121 to the tank 80. The cleaning liquid is, for example, DIW (deionized water). The seventh valve 122 is an opening/closing valve provided in a flow path of the cleaning liquid supplied from the cleaning liquid source 121. For example, when the controller 18 controls the cleaning liquid supplier 120 to open the seventh valve 122, the cleaning liquid supplied from the cleaning liquid source 121 is sent to the tank 80 via the seventh valve 122. Further, when the controller 18 controls the cleaning liquid supplier 120 to close the seventh valve 122, the cleaning liquid is not sent from the cleaning liquid source 121 to the tank 80.

The new liquid supplier 130 supplies a new processing liquid to the tank 80. The new liquid supplier 130 includes a new liquid source 131 and an eighth valve 132. The new processing liquid is supplied from the new liquid source 131 to the tank 80. The eighth valve 132 is an open/close valve provided in a flow path of the new processing liquid supplied from the new liquid source 131. For example, when the controller 18 controls the new liquid supplier 130 to open the eighth valve 132, the new processing liquid supplied from the new liquid source 131 is sent to the tank 80 via the eighth valve 132. Further, when the controller 18 controls the new liquid supplier 130 to close the eighth valve 132, the new processing liquid is not sent from the new liquid source 131 to the tank 80.

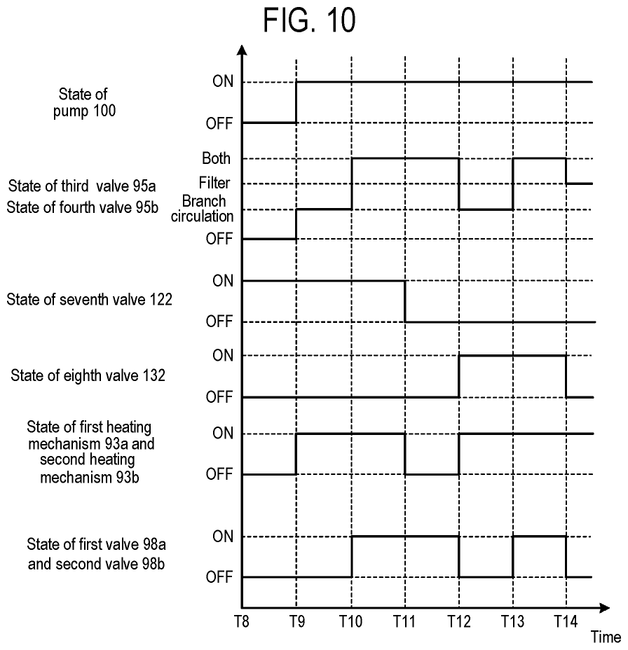

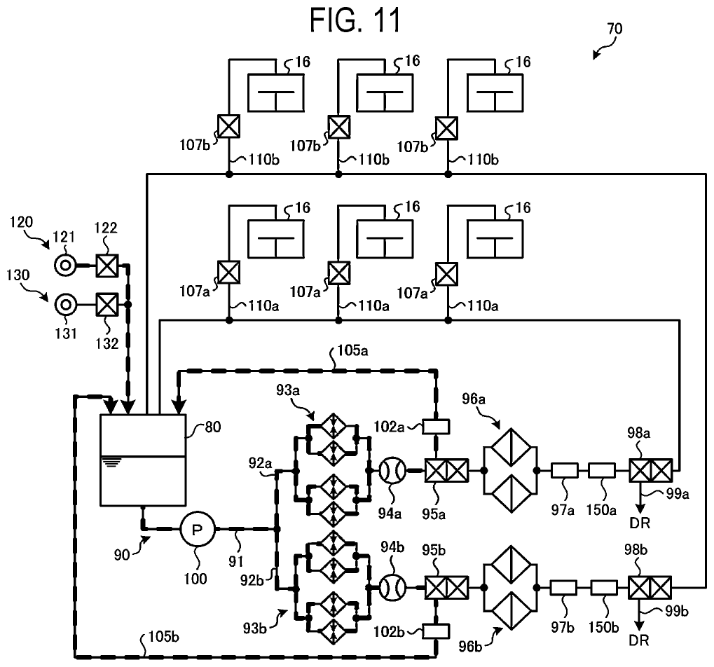

Next, an example of an operation of the substrate processing system 1 according to the third embodiment will be described with reference to FIG. 10. FIG. 10 is a diagram showing an example of transitions of states of the pump 100, the first valve 98a to the fourth valve 95b, the seventh valve 122, the eighth valve 132, the first heating mechanism 93a, and the second heating mechanism 93b. For example, FIG. 10 shows an example of the transitions of the states of the respective components when the filter 96 is replaced with a new one and the replaced filter 96 is cleaned after the circulation of the processing liquid in the circulation line 90 has stopped. FIGS. 11 to 14 are schematic diagrams showing an example of the operation of the processing liquid source 70 according to the third embodiment.

First, the controller 18 controls the seventh valve 122 to start supplying the cleaning liquid to the tank 80 (time T8).

Subsequently, the controller 18 operates the pump 100 in the stopped state to pump the cleaning liquid from the tank 80 to the circulation line 90 (time T9). The controller 18 also controls the third valve 95a and the fourth valve 95b such that the cleaning liquid flows into the first branch circulation line 105a and the second branch circulation line 105b. The controller 18 also operates the first heating mechanism 93a and the second heating mechanism 93b. As a result, the cleaning liquid supplied from the cleaning liquid source 121 to the tank 80 flows into the first branch circulation line 105a and the second branch circulation line 105b via the third valve 95a and the fourth valve 95b, and is heated while circulating back to the tank 80 (see FIG. 11).

Subsequently, the controller 18 determines whether or not the temperature of the cleaning liquid flowing through the first branch circulation line 105a and the second branch circulation line 105b has stabilized based on the detection results by the first branch temperature sensor 102a and the second branch temperature sensor 102b. Specifically, when the measurement value by the first branch temperature sensor 102a falls within a preset threshold range in a preset monitoring time width, the controller 18 determines that the temperature of the cleaning liquid in the first branch circulation line 105a has stabilized. Similarly, when the measurement value by the second branch temperature sensor 102b falls within a preset threshold range in a preset monitoring time width, the controller 18 determines that the temperature of the cleaning liquid in the second branch circulation line 105b has stabilized.

When the temperatures of the cleaning liquid in the first branch line 92a and the second branch line 92b have stabilized, the controller 18 controls the first to fourth valves 98a to 95b such that the processing liquid flows into the drain line 99 while circulating through the first branch circulation line 105a and the second branch circulation line 105b. For example, as shown in FIG. 10, after the measurement values by the first branch temperature sensor 102a and the second branch temperature sensor 102b fall within the preset threshold range in the preset monitoring time width, the controller 18 controls the third valve 95a and the fourth valve 95b such that the cleaning liquid flows into both the filter 96 and the branch circulation line 105 (time T10).

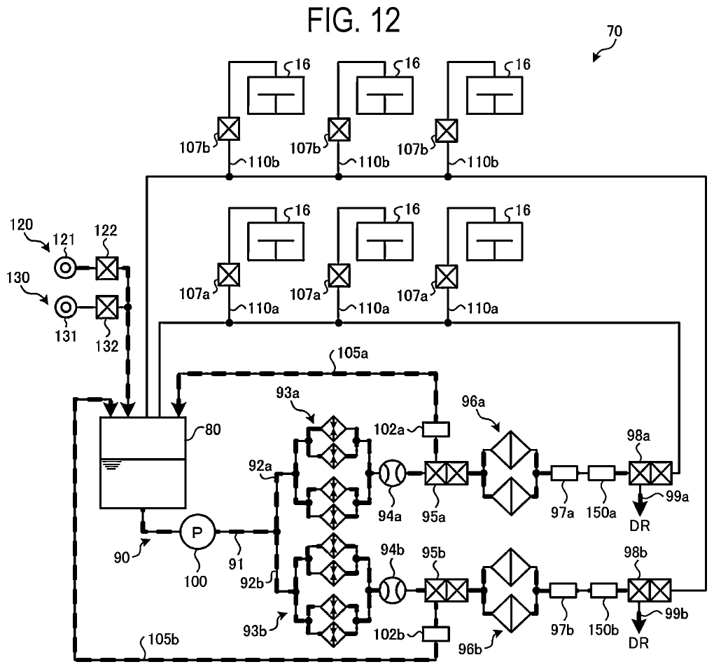

At the same time, the controller 18 controls the first valve 98a and the second valve 98b such that the cleaning liquid flows into the first drainage line 99a and the second drainage line 99b. As a result, the cleaning liquid sent from the tank 80 flows into the first branch circulation line 105a or the second branch circulation line 105b and circulates back to the tank 80, during which the cleaning liquid flows into the first filter 96a and the second filter 96b and is drained from the drain line 99 (see FIG. 12). Thereafter, the controller 18 controls the seventh valve 122 to stop the supply of the cleaning liquid to the tank 80 (time T11). In addition, the controller 18 stops the operation of the first heating mechanism 93a and the second heating mechanism 93b. As a result, the cleaning liquid in the tank 80 flows into the first filter 96a and the second filter 96b and is drained from the drain line 99. Therefore, the cleaning liquid gradually decreases, and finally, the entire cleaning liquid in the tank 80 is drained.

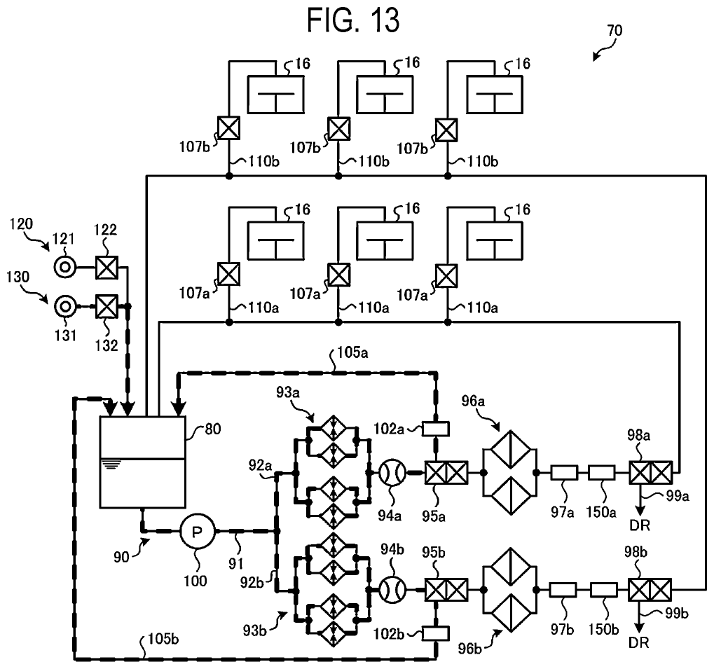

Subsequently, the controller 18 controls the eighth valve 132 to supply a new processing liquid to the tank 80 (time T12). The controller 18 also controls the third valve 95a and the fourth valve 95b such that the processing liquid flows into the first branch circulation line 105a and the second branch circulation line 105b. The controller 18 also operates the first heating mechanism 93a and the second heating mechanism 93b. As a result, the new processing liquid supplied from the new liquid source 131 to the tank 80 flows into the first branch circulation line 105a and the second branch circulation line 105b via the third valve 95a and the fourth valve 95b, and is heated while circulating back to the tank 80 (see FIG. 13).

Subsequently, the controller 18 determines whether or not temperatures of the processing liquid flowing through the first branch circulation line 105a and the second branch circulation line 105b have stabilized based on the detection results by the first branch temperature sensor 102a and the second branch temperature sensor 102b.

When the temperatures of the processing treatment liquid in the first branch line 92a and the second branch line 92b is determined to be stabilized, the controller 18 controls the first to fourth valves 98a to 95b such that the processing liquid flows into the drain line 99 while circulating through the first branch circulation line 105a and the second branch circulation line 105b. For example, as shown in FIG. 10, after the measurement values by the first branch temperature sensor 102a and the second branch temperature sensor 102b fall within the preset threshold range in the preset monitoring time width, the controller 18 controls the third valve 95a and the fourth valve 95b such that the processing liquid flows into both the filter 96 and the branch circulation line 105 (time T13).

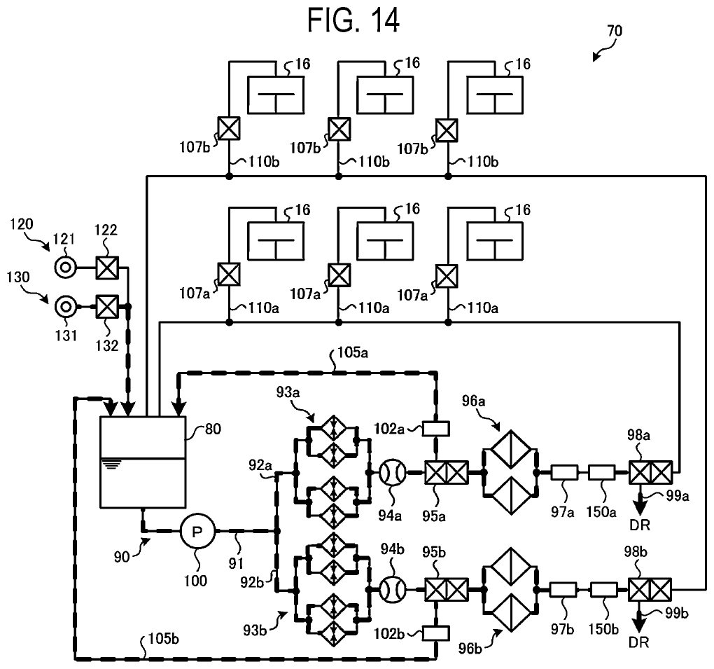

At the same time, the controller 18 controls the first valve 98a and the second valve 98b such that the processing liquid flows into the first drain line 99a and the second drain line 99b. As a result, the processing liquid sent from the tank 80 flows through the first branch circulation line 105a or the second branch circulation line 105b and circulates back to the tank 80, during which the processing liquid flows into the first filter 96a and the second filter 96b and is drained from the drain line 99 (see FIG. 14).

Subsequently, the controller 18 determines whether or not to drain the processing liquid from the drain line 99 based on the detection results by the first circulation temperature sensor 97a and the second circulation temperature sensor 97b. Specifically, when the measurement values by the first circulation temperature sensor 97a and the second circulation temperature sensor 97b are equal to or higher than a threshold value, the controller 18 controls the first to fourth valves 98a to 95b to switch the destination of the processing liquid from the drain line 99 to the supply line 110.

For example, as shown in FIG. 10, when the measurement values by both the first circulation temperature sensor 97a and the second circulation temperature sensor 97b are equal to or greater than the threshold value, the controller 18 controls the third valve 95a and the fourth valve 95b to switch the destination of the processing liquid to the filter 96 (time T14). At the same time, the controller 18 controls the first valve 98a and the second valve 98b to switch the destination of the processing liquid to the supply line 110. In addition, the controller 18 controls the eighth valve 132 to stop the supply of the processing liquid to the tank 80. As a result, the processing liquid sent from the tank 80 flows into the first branch line 92a and the second branch line 92b and returns to the tank 80. In addition, when the fifth valve 107a or the sixth valve 107b is open, the processing liquid is supplied from the supply line 110 to the processing unit 16.

As described above, the controller 18 sends the cleaning liquid having a predetermined temperature or higher to the filter 96. Specifically, when the temperature of the cleaning liquid circulating through the branch circulation line 105 is determined to be stabilized based on the detection results by the first circulation temperature sensor 97a and the second circulation temperature sensor 97b, the controller 18 controls the pump 100 to send the cleaning liquid to the filter 96 (time T10).

By supplying the cleaning liquid having a predetermined temperature or higher to the filter 96, it is possible to remove particles adhering to the replaced filter 96, for example, particles adhering to the replaced filter 96 during a replacement operation or the like.

The controller 18 also controls the first valve 98a and the second valve 98b to drain the cleaning liquid having a predetermined temperature or higher, which has sent to the filter 96, from the drain line 99 for a predetermined period of time (time T10).

Thus, after the particles adhering to the first filter 96a and the second filter 96b are removed, the cleaning liquid may be drained. This makes it possible to reduce contamination of the interior of the circulation line 90 by the particles.

In addition, after the cleaning liquid sent to the filter 96 is drained from the drain line 99, the controller 18 controls the cleaning liquid supplier 120 to stop the supply of the cleaning liquid to the tank 80, and controls the new liquid supplier 130 to start the supply of the new processing liquid to the tank 80 (time T10 to time T12).

By supplying the new processing liquid and allowing it to flow through the circulation line 90 in this manner, new particles are less likely to adhere to the filter 96 that has been cleaned with the cleaning liquid.

In addition, the controller 18 controls the seventh valve 122 to start supplying the cleaning liquid to the tank 80, and then controls the pump 100, the first heating mechanism 93a, and the second heating mechanism 93b to heat the cleaning liquid while allowing the cleaning liquid to circulate through the first branch circulation line 105a and the second branch circulation line 105b (time T8 to time T10).

As described above, by heating the cleaning liquid while allowing the cleaning liquid to circulate through the first branch circulation line 105a and the second branch circulation line 105b under the control of the controller 18, the cleaning liquid may be efficiently heated in a short time compared to a case where the cleaning liquid is heated while allowing the cleaning liquid to circulate throughout the entire circulation line 90.

Further, the temperature of the cleaning liquid sent to the filter 96 may be higher than that of the processing liquid sent to the filter 96. Specifically, the lower limit of the threshold range used to determine whether or not the temperature of the cleaning liquid has stabilized may be higher than that of the threshold range used to determine whether or not the temperature of the processing liquid has stabilized. By setting the threshold range in this manner, the temperature of the cleaning liquid sent to the filter 96 becomes higher than the temperature of the processing liquid sent to the filter 96.

As shown in FIG. 9, the processing liquid source 70 according to the third embodiment may further include moisture concentration meters 150 (a first moisture concentration meter 150a and a second moisture concentration meter 150b). The moisture concentration meters 150 are provided in the circulation line 90 to measure a moisture concentration of the liquid flowing through the circulation line 90.

Based on the measurement results by the moisture concentration meters 150, the controller 18 may check a ratio of the cleaning liquid in the liquid flowing through the circulation line 90. This makes it possible to check a degree of replacement of the liquid in the liquid flowing through the circulation line 90 from the cleaning liquid to the processing liquid.

Although in the above, the example in which two moisture concentration meters, i.e., the first moisture concentration meter 150a and the second moisture concentration meter 150b has been described to to provided, the present disclosure is not limited thereto. Only one of the two moisture concentration meters may be provided.

By sending the high-temperature cleaning liquid to the filter 96 in this manner, the filter 96 thermally expands. Therefore, the particles trapped in the filter 96 may be easily released from the filter 96. Since the particles released from the filter 96 may be drained together with the cleaning liquid into the drain line 99, it is possible to reduce contamination of the interior of the circulation line 90 by the particles.

As described above, the controller 18 sends the cleaning liquid having a predetermined temperature or higher to the filter 96. This makes it possible to remove particles adhering to the replaced filter 96, for example, particles adhering to the replaced filter 96 during a replacement operation.

Although in the above, the example in which the filter 96 to be cleaned with the cleaning liquid is a new replaced filter has been described, the filter 96 to be cleaned is not limited thereto. For example, the filter 96 may be a filter that has become contaminated through use. By cleaning the filter that has become contaminated through use with the cleaning liquid having a predetermined temperature or higher, it is possible to remove particles that have adhered to the filter through use. In addition, the filter may be cleaned inexpensively and easily compared to the case of cleaning the filter using an external device.

Further, by cleaning the filter using the branch circulation line 105, the filter may be cleaned in a shorter time than when the entire circulation line 90 is used to clean the filter. This reduces an amount of cleaning liquid used.

### Fourth Embodiment

In the first embodiment described above, the example has been described in which the destination of the processing liquid is switched from the drain line 99 to the supply line 110 when the temperature of the processing liquid flowing through the circulation line 90 is equal to or higher than the threshold value at time T7 in FIG. 4. However, the present disclosure is not limited thereto. For example, when the temperature of the processing liquid flowing through the circulation line 90 is equal to or higher than the threshold value, the processing liquid may be continuously drained during a predetermined period of time.

By switching the destination of the processing liquid from the drain line 99 to the supply line 110, a circulation flow rate of the processing liquid flowing through the circulation line 90 may increase. Specifically, when the processing liquid circulates only through the branch circulation line 105 while being heated, the circulation flow rate is adjusted to be less than a predetermined circulation flow rate in order to stabilize the temperature of the processing liquid. Thereafter, when the destination of the processing liquid is switched from the drain line 99 to the supply line 110, the circulation flow rate of the processing liquid is adjusted to be equal to or greater than the predetermined circulation flow rate. In such a case, the circulation flow rate of the processing liquid flowing through the circulation line 90 increases. When the circulation flow rate of the processing liquid flowing through the circulation line 90 increases, particles trapped in the filter 96 may be released from the filter 96, thereby causing contamination of the processing liquid in the circulation line 90.

Therefore, when the temperature of the processing liquid flowing through the circulation line 90 becomes equal to or higher than the threshold value as described above, the controller 18 continues to drain the processing liquid during the predetermined period of time. Specifically, when the temperature of the processing liquid flowing through the circulation line 90 becomes equal to or higher than the threshold value, the controller 18 controls the first valve 98a and the second valve 98b to switch the destination of the processing liquid to the drain line 99 and the supply line 110. As a result, the processing liquid sent from the tank 80 is drained at a constant rate from the drain line 99 while flowing into the branch line 92. Thereafter, for example, after the predetermined period of time, the controller 18 switches the destination of the processing liquid from the drain line 99 and the supply line 110 to the supply line 110.

As a result, when the particles trapped in the first filter 96a and the second filter 96b are released due to a change in the circulation flow rate of the processing liquid, the processing liquid may be drained. Therefore, it is possible to reduce contamination of the processing liquid in the circulation line 90 by the particles.

### Fifth Embodiment

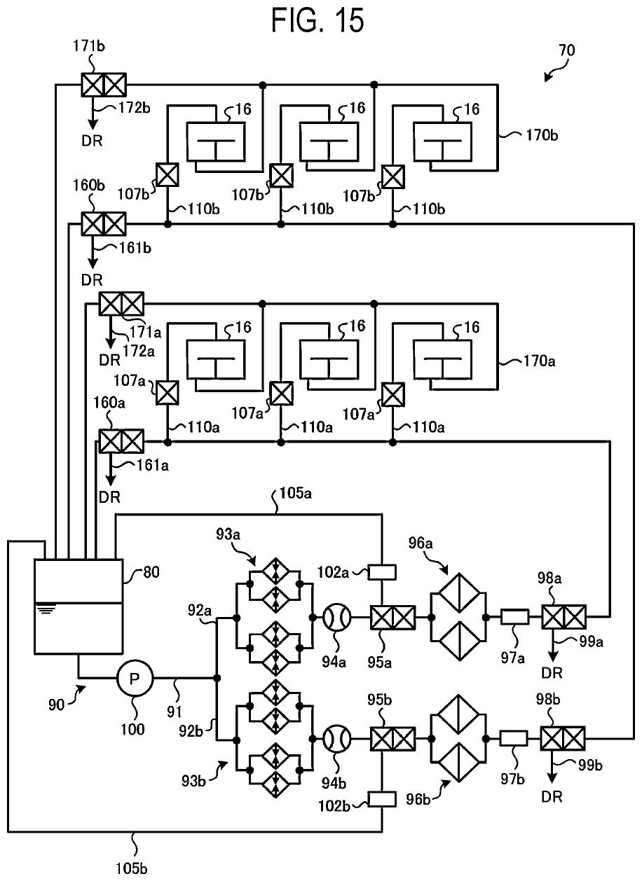

FIG. 15 is a diagram showing a schematic configuration of a processing liquid source 70 according to a fifth embodiment. The processing liquid source 70 according to the fifth embodiment differs from the processing liquid source 70 according to the first embodiment in that the processing liquid source 70 according to the fifth embodiment includes valves 160, liquid sending lines 170, and valves 171.

The valves 160 (a ninth valve 160a and a tenth valve 160b) are located downstream of a connection point of the branch line 92 with the supply line 110. The valves 160 switch the destination of the processing liquid. Specifically, a third drain line 161a connected to the drain part DR branches from the ninth valve 160a. The third drain line 161a drains the processing liquid flowing into the first branch line 92a. The ninth valve 160a switches the destination of the processing liquid in the first branch line 92a between the third drain line 161a and the first branch line 92a. Similarly, a fourth drain line 161b connected to the drain part DR branches from the tenth valve 160b. The fourth drain line 161b drains the processing liquid flowing into the second branch line 92b. The tenth valve 160b switches the destination of the processing liquid in the second branch line 92b between the fourth drain line 161b and the second branch line 92b.

The liquid sending lines 170 (a first liquid sending line 170a and a second liquid sending line 170b) return the processing liquid supplied to the processing unit 16 to the tank 80. The liquid sending lines 170 are provided with the valves 171 (an eleventh valve 171a and a twelfth valve 171b). The valves 171 switch the destination of the processing liquid. Specifically, the fifth drain line 172a connected to the drain part DR branches from the eleventh valve 171a. The fifth drain line 172a drains the processing liquid flowing through the first liquid sending line 170a. The eleventh valve 171a switches the destination of the processing liquid in the first liquid sending line 170a between the fifth drain line 172a and the first liquid sending line 170a. Similarly, the sixth drain line 172b connected to the drain part DR branches from the twelfth valve 171b. The sixth drain line 172b drains the processing liquid flowing through the second liquid sending line 170b. The twelfth valve 171b switches the destination of the processing liquid in the second liquid sending line 170b between the sixth drain line 172b and the second liquid sending line 170b.

Since the processing liquid source 70 according to the fifth embodiment includes the valves 160 or the valves 171 as described above, it is possible to drain the processing liquid staying for a long time in the branch line 92 or the liquid sending line 170. Specifically, in an operation of circulating the processing liquid in the circulation line 90 again after the circulation of the processing liquid has been stopped for maintenance or the like, the controller 18 controls the valves 160 or the valves 171 to switch the destination of the processing liquid to the third to sixth drain lines 161a to 172b for a certain period of time. As a result, the processing liquid staying for a long time may be drained without being returned to the tank 80. Therefore, the tank 80 or the circulation line 90 is less likely to be contaminated by the staying processing liquid.

### Sixth Embodiment

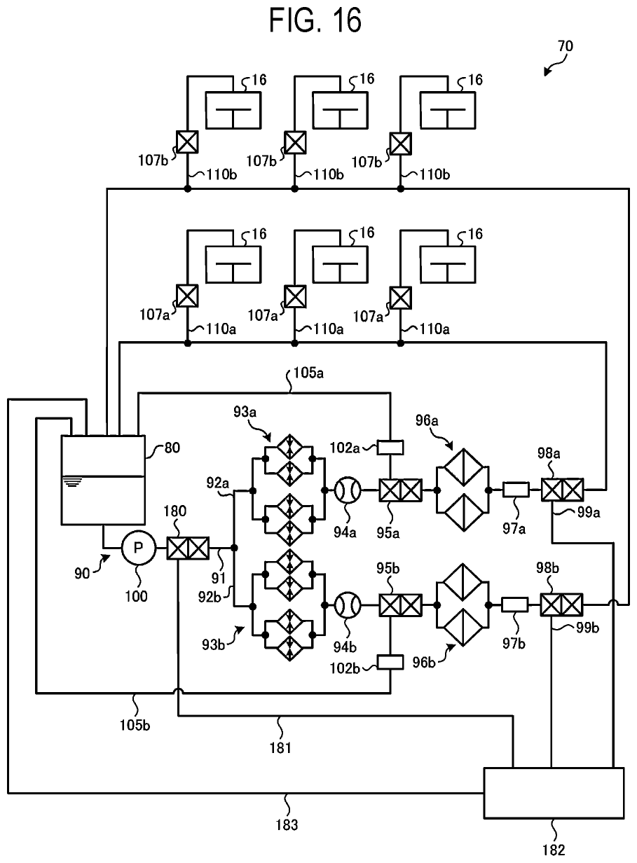

FIG. 16 is a diagram showing a schematic configuration of a processing liquid source 70 according to a sixth embodiment. The processing liquid source 70 according to the sixth embodiment differs from the processing liquid source 70 according to the first embodiment in that the processing liquid source 70 according to the sixth embodiment includes a valve 180 and a filtration tank 182 and further that the processing liquid is sent to the filtration tank 182 by the valves 98.

The valve 180 is located downstream of the pump 100 in the main line 91. The valve 180 switches the destination of the processing liquid. Specifically, a filtration line 181 connected to the filtration tank 182 branches from the valve 180a. The filtration line 181 sends the processing liquid flowing through the main line 91 to the filtration tank 182. The valve 180a switches the destination of the processing liquid in the main line 91 between the filtration line 181 and the main line 91.

The valves 98 (the first valve 98a and the second valve 98b) switch the destination of the processing liquid. Specifically, the first drain line 99a connected to the filtration tank 182 branches from the first valve 98a. The first drain line 99a sends the processing liquid flowing through the first branch line 92a to the filtration tank 182. Similarly, the second drain line 99b connected to the filtration tank 182 branches from the second valve 98b. The second drain line 99b sends the processing liquid flowing through the first branch line 92a to the filtration tank 182.

The filtration tank 182 removes contaminants and the like contained in the sent processing liquid using a filter material or the like. The processing liquid from which the contaminants and the like have been removed by the filtration tank 182 flows into the supply line 183 and is sent to the tank 80.

Since the processing liquid source 70 according to the sixth embodiment includes the filtration tank 182 as described above, it is possible to filter the processing liquid flowing through the drain line 99 or the circulation line 90 and return the processing liquid to the tank 80 and the circulation line 90 for reuse. Therefore, it is possible to reduce an amount of processing liquid drained.

The present disclosure may have the following configurations.
(1) A liquid supply device includes: a processing liquid line through which a processing liquid is supplied to a liquid processor configured to perform liquid processing on a substrate; a heating mechanism provided in the processing liquid line and configured to heat the processing liquid flowing through the processing liquid line; a filter provided downstream of the heating mechanism in the processing liquid line; a drain line provided downstream of the filter in the processing liquid line and through which the processing liquid flowing through the processing liquid line is drained; a first temperature sensor provided in the filter, the processing liquid line located between the filter and the drain line, or the drain line, and configured to respectively detect a temperature of the filter, the processing liquid line, or the drain line, or to detect a temperature of the processing liquid; and a controller. The controller is configured to determine whether or not to drain the processing liquid from the drain line based on a detection result obtained by the first temperature sensor.
(2) The liquid supply device of (1) above further includes a tank configured to store the processing liquid. The processing liquid line includes a circulation line through which the processing liquid sent from the tank returns to the tank, a pump configured to form a circulation flow of the processing liquid in the circulation line, and a branch circulation line branching from between the heating mechanism and the filter and configured to return the processing liquid sent from the tank to the tank. The controller is configured to, before starting circulation of the processing liquid in the circulation line, control the pump and the heating mechanism to heat the processing liquid while allowing the processing liquid to circulate in the branch circulation line.
(3) The liquid supply device of (2) above further includes a second temperature sensor provided in the branch circulation line and configured to detect a temperature of the processing liquid flowing through the branch circulation line. When the temperature of the processing liquid circulating through the branch circulation line is determined to be stabilized based on a detection result by the second temperature sensor, the controller controls the pump to send the processing liquid to the filter.
(4) The liquid supply device of (3) above further includes a supply line branching downstream of the drain line in the circulation line and through which the processing liquid is supplied to the liquid processor; and a valve configured to switch a destination of the processing liquid between the drain line and the supply line in the circulation line. The controller is configured to control the valve such that the processing liquid sent to the filter flows into the drain line and is drained via the drain line.
(5) In the liquid supply device of any one of (2) to (4) above, the controller is configured to repeatedly perform an operation of, before starting circulation of the processing liquid in the circulation line, heating the processing liquid while allowing the processing liquid to circulate through the branch circulation line, sending the processing liquid circulating through the branch circulation line to the filter, and draining the processing liquid sent to the filter into the drain line.
(6) In the liquid supply device of (4) above, when the temperature of the filter, the processing liquid line, the drain line or the processing liquid is determined to be equal to or higher than a threshold value based on the detection result by the first temperature sensor, the controller controls the valve to switch the destination of the processing liquid from the drain line to the supply line.
(7) In the liquid supply device of (4) above, when the temperature of the filter, the processing liquid line, the drain line or the processing liquid is determined to be equal to or higher than a threshold value based on the detection result of the first temperature sensor, the controller controls the valve to switch the destination of the processing liquid from the drain line to the supply line and the drain line.
(8) In the liquid supply device of (7) above, the controller switches the destination of the processing liquid from the drain line to the supply line and the drain line, and subsequently, switches the destination of the processing liquid from the supply line and the drain line to the supply line.
(9) In the liquid supply device of (2) above, the controller circulates the processing liquid in the branch circulation line while circulating the processing liquid in the circulation line.
(10) A liquid supply device includes: a processing liquid line through which a processing liquid is supplied to a liquid processor configured to perform liquid processing on a substrate; a heating mechanism provided in the processing liquid line and configured to heat the processing liquid flowing through the processing liquid line; a filter provided downstream of the heating mechanism in the processing liquid line; a drain line provided downstream of the filter in the processing liquid line and through which the processing liquid flowing through the processing liquid line is drained; a tank configured to store the processing liquid; a cleaning liquid supplier configured to supply a cleaning liquid for the filter to the tank; and a controller. The processing liquid includes a circulation line through which the processing liquid sent from the tank returns to the tank, a pump configured to form a circulation flow of the processing liquid in the circulation line, and a branch circulation line branching from between the heating mechanism and the filter and configured to return the processing liquid sent from the tank to the tank. The controller controls the cleaning liquid supplier to start supplying the cleaning liquid to the tank, and subsequently, controls the pump and the heating mechanism to heat the cleaning liquid while allowing the cleaning liquid to circulate through the branch circulation line.
(11) The liquid supply device of (10) above further includes a second temperature sensor provided in the branch circulation line and configured to detect a temperature of the cleaning liquid flowing through the branch circulation line. When the temperature of the cleaning liquid circulating through the branch circulation line is determined to be stabilized based on a detection result by the second temperature sensor, the controller controls the pump to send the cleaning liquid to the filter.
(12) The liquid supply device of (11) above further includes: a supply line branching downstream of the drain line in the circulation line and through which the processing liquid is supplied to the liquid processor; and a valve configured to switch a destination of the processing liquid between the drain line and the supply line in the circulation line. The controller is configured to control the valve such that the processing liquid having a predetermined temperature or higher sent to the filter flows into the drain line and is drained via the drain line for a predetermined period of time.
(13) The liquid supply device of (12) above further includes a new liquid supplier configured to supply a new processing liquid to the tank. After the cleaning liquid sent to the filter is drained via the drain line, the controller controls the cleaning liquid supplier to stop supplying the cleaning liquid to the tank and controls the new liquid supplier to start supplying the new processing liquid to the tank.
(14) In the liquid supply device of (11) above, the temperature of the cleaning liquid sent to the filter is higher than the temperature of the processing liquid sent to the filter.
(15) A liquid supply method performed in the liquid supply device of (1) above includes: detecting, by the first temperature sensor, the temperature of the filter, the processing liquid line, the drain line, or the processing liquid; and determining whether or not to drain the processing liquid from the drain line based on the detection result by the first temperature sensor.
(16) A liquid supply method performed in the liquid supply device of (1) above includes: detecting, by the first temperature sensor, the temperature of the filter, the processing liquid line, the drain line, or the processing liquid; and supplying the processing liquid flowing through the processing liquid line to the liquid processor when the temperature of the filter, the processing liquid line, the drain line, or the processing liquid is determined to be equal to or higher than a threshold value based on the detection result by the first temperature sensor.
(17) In a non-transitory computer-readable storage medium storing a program that operates on a computer to control a liquid supply device, the program, when executed, causes the computer to control the liquid supply device so as to perform the liquid supply method of (15) or (16) above.

According to the present disclosure in some embodiments, it is possible to reduce contamination of a processing liquid in a circulation line.

While certain embodiments have been described, these embodiments have been presented by way of example only, and are not intended to limit the scope of the disclosures. Indeed, the embodiments described herein may be embodied in a variety of other forms. Further, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A liquid supply device, comprising:
a processing liquid line through which a processing liquid is supplied to a liquid processor configured to perform liquid processing on a substrate;
a heating mechanism provided in the processing liquid line and configured to heat the processing liquid flowing through the processing liquid line;
a filter provided downstream of the heating mechanism in the processing liquid line;
a drain line provided downstream of the filter in the processing liquid line and through which the processing liquid flowing through the processing liquid line is drained;
a first temperature sensor provided in the filter, the processing liquid line located between the filter and the drain line, or the drain line, and configured to respectively detect a temperature of the filter, the processing liquid line, or the drain line, or to detect a temperature of the processing liquid; and
a controller,
wherein the controller is configured to determine whether or not to drain the processing liquid from the drain line based on a detection result obtained by the first temperature sensor.

2. The liquid supply device of claim 1, further comprising:
a tank configured to store the processing liquid,
wherein the processing liquid line includes a circulation line through which the processing liquid sent from the tank returns to the tank, a pump configured to form a circulation flow of the processing liquid in the circulation line, and a branch circulation line branching from between the heating mechanism and the filter and configured to return the processing liquid sent from the tank to the tank, and
wherein the controller is configured to, before starting circulation of the processing liquid in the circulation line, control the pump and the heating mechanism to heat the processing liquid while allowing the processing liquid to circulate in the branch circulation line.

3. The liquid supply device of claim 2, further comprising:
a second temperature sensor provided in the branch circulation line and configured to detect a temperature of the processing liquid flowing through the branch circulation line,
wherein, when the temperature of the processing liquid circulating through the branch circulation line is determined to be stabilized based on a detection result by the second temperature sensor, the controller controls the pump to send the processing liquid to the filter.

4. The liquid supply device of claim 3, further comprising:
a supply line branching downstream of the drain line in the circulation line and through which the processing liquid is supplied to the liquid processor; and
a valve configured to switch a destination of the processing liquid between the drain line and the supply line in the circulation line,
wherein the controller is configured to control the valve such that the processing liquid sent to the filter flows into the drain line and is drained via the drain line.

5. The liquid supply device of claim 4, wherein the controller is configured to repeatedly perform an operation of, before starting circulation of the processing liquid in the circulation line, heating the processing liquid while allowing the processing liquid to circulate through the branch circulation line, sending the processing liquid circulating through the branch circulation line to the filter, and draining the processing liquid sent to the filter into the drain line.

6. The liquid supply device of claim 4, wherein, when the temperature of the filter, the processing liquid line, the drain line or the processing liquid is determined to be equal to or higher than a threshold value based on the detection result by the first temperature sensor, the controller controls the valve to switch the destination of the processing liquid from the drain line to the supply line.

7. The liquid supply device of claim 4, wherein, when the temperature of the filter, the processing liquid line, the drain line or the processing liquid is determined to be equal to or higher than a threshold value based on the detection result of the first temperature sensor, the controller controls the valve to switch the destination of the processing liquid from the drain line to the supply line and the drain line.

8. The liquid supply device of claim 7, wherein the controller switches the destination of the processing liquid from the drain line to the supply line and the drain line, and subsequently, switches the destination of the processing liquid from the supply line and the drain line to the supply line.

9. The liquid supply device of claim 2, wherein the controller circulates the processing liquid in the branch circulation line while circulating the processing liquid in the circulation line.

10. A liquid supply device, comprising:
a processing liquid line through which a processing liquid is supplied to a liquid processor configured to perform liquid processing on a substrate;
a heating mechanism provided in the processing liquid line and configured to heat the processing liquid flowing through the processing liquid line;
a filter provided downstream of the heating mechanism in the processing liquid line;
a drain line provided downstream of the filter in the processing liquid line and through which the processing liquid flowing through the processing liquid line is drained;
a tank configured to store the processing liquid;
a cleaning liquid supplier configured to supply a cleaning liquid for the filter to the tank; and
a controller,
wherein the processing liquid includes a circulation line through which the processing liquid sent from the tank returns to the tank, a pump configured to form a circulation flow of the processing liquid in the circulation line, and a branch circulation line branching from between the heating mechanism and the filter and configured to return the processing liquid sent from the tank to the tank, and
wherein the controller controls the cleaning liquid supplier to start supplying the cleaning liquid to the tank, and subsequently, controls the pump and the heating mechanism to heat the cleaning liquid while allowing the cleaning liquid to circulate through the branch circulation line.

11. The liquid supply device of claim 10, further comprising:
a second temperature sensor provided in the branch circulation line and configured to detect a temperature of the cleaning liquid flowing through the branch circulation line,
wherein, when the temperature of the cleaning liquid circulating through the branch circulation line is determined to be stabilized based on a detection result by the second temperature sensor, the controller controls the pump to send the cleaning liquid to the filter.

12. The liquid supply device of claim 11, further comprising:
a supply line branching downstream of the drain line in the circulation line and through which the processing liquid is supplied to the liquid processor; and
a valve configured to switch a destination of the processing liquid between the drain line and the supply line in the circulation line,
wherein the controller is configured to control the valve such that the processing liquid having a predetermined temperature or higher sent to the filter flows into the drain line and is drained via the drain line for a predetermined period of time.

13. The liquid supply device of claim 12, further comprising:
a new liquid supplier configured to supply a new processing liquid to the tank,
wherein, after the cleaning liquid sent to the filter is drained via the drain line, the controller controls the cleaning liquid supplier to stop supplying the cleaning liquid to the tank and controls the new liquid supplier to start supplying the new processing liquid to the tank.

14. The liquid supply device of claim 11, wherein the temperature of the cleaning liquid sent to the filter is higher than a temperature of the processing liquid sent to the filter.

15. A liquid supply method performed in the liquid supply device of claim 1, the liquid supply method comprising:
detecting, by the first temperature sensor, the temperature of the filter, the processing liquid line, the drain line, or the processing liquid; and
determining whether or not to drain the processing liquid from the drain line based on the detection result by the first temperature sensor.

16. A liquid supply method performed in the liquid supply device of claim 1, the liquid supply method comprising:
detecting, by the first temperature sensor, the temperature of the filter, the processing liquid line, the drain line, or the processing liquid; and
supplying the processing liquid flowing through the processing liquid line to the liquid processor when the temperature of the filter, the processing liquid line, the drain line, or the processing liquid is determined to be equal to or higher than a threshold value based on the detection result by the first temperature sensor.

17. A non-transitory computer-readable storage medium storing a program that operates on a computer to control a liquid supply device,
wherein the program, when executed, causes the computer to control the liquid supply device so as to perform the liquid supply method of claim 15.

18. A non-transitory computer-readable storage medium storing a program that operates on a computer to control a liquid supply device,
wherein the program, when executed, causes the computer to control the liquid supply device so as to perform the liquid supply method of claim 16.
